(19) United States
(12) Patent Application Publication
(10) Pub. No.: US 2006/0211259 A1
(43) Pub. Date: Sep. 21, 2006

(54) Silicon oxide cap over high dielectric constant films

(76) Inventors: Jan Willem Maes, Wilrijk (BE); Hilde De Witte, Thisnes-Hannut (BE); Christophe Pomarede, Phoenix, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/087,079

(22) Filed: Mar. 21, 2005

(51) Int. Cl. H01L 21/336

(52) U.S. Cl. 438/762

(57) ABSTRACT

A method for forming an integrated circuit structure on a semiconductor substrate comprises depositing a high k gate dielectric material over the substrate using an atomic layer deposition process. A silicon oxide capping layer is deposited over the gate dielectric material in a rapid thermal chemical vapor deposition process. A gate electrode is formed over the silicon oxide capping layer.

### FIELD OF THE INVENTION

The present invention relates generally to forming semiconductor layers in integrated circuit fabrication, and relates more specifically to formation of a silicon oxide cap layer over a high dielectric constant material.

### BACKGROUND OF THE INVENTION

The thin film transistor (TFT) is a fundamental integrated circuit component. A TFT is a layered structure that typically includes a gate electrode separated from a semiconductor layer by a thin gate dielectric layer. Although a common acronym for state-of-the-art transistors is MOS, for metal-oxide-silicon, the material of choice for the gate electrode has long been silicon rather than metal. Among other advantages, silicon gate electrodes are able to withstand high temperature processes and enable self-aligned doping processes used for completing the transistor, thus eliminating expensive masking steps. Currently many metal materials are being explored to replace silicon as the gate electrode; this replacement would allow work functions to be matched with channel regions of the transistor, and would also increase device speed.

Conventional gate dielectrics are formed of high quality silicon dioxide (SiO₂), silicon oxynitride (SiON), or oxide-nitride-oxide (ONO) trilayers, and are typically referred to as gate oxide layers. However, ultra thin gate oxides (for example, less than 5 nm) have been found to exhibit high defect densities, including pinholes, charge trapping states, and susceptibility to hot carrier injection effects. Such high defect densities lead to leakage currents through the gate dielectric. This results in rapid device breakdown for circuit designs with less than 0.25 μm gate spacing (“sub-quarter-micron technology”).

While care under laboratory conditions can be used to control defect densities, such control has been difficult to achieve under commercial volume fabrication conditions. Moreover, even if the integrity of the oxide is perfectly maintained, quantum mechanical effects set fundamental limits on the scaling of the gate oxide. At high electric field strengths, direct tunneling dominates over Fowler-Nordheim tunneling, and largely determines oxide scaling limits. These scaling limits have been estimated at about 2 nm for logic circuits, and about 3 nm for more leakage-sensitive memory arrays in dynamic random access memory (DRAM) circuits. See, for example, Hu et al., Thin Gate Oxides Promise High Reliability, Semiconductor International (July 1998), pages 215-222.

Incorporating materials of higher dielectric constant into the gate dielectric opens the door to further device scaling. Higher dielectric constant materials can exhibit the same capacitance as a thinner silicon dioxide layer, such that a lower equivalent oxide thickness can be achieved without tunnel-limited behavior. Silicon nitride (Si₃N₄) has a slightly higher dielectric constant than SiO₂ and also demonstrates good diffusion barrier properties, resisting boron penetration, but has demonstrated poor interface properties. More exotic materials with even higher dielectric constants, including aluminum oxide (Al₂O₃), zirconium oxide (ZrO₂), hafnium-based oxides (HfO₂, AlHfO, HfSiOₓ, HfSiON), barium strontium titanate (BST), strontium bismuth tantalate (SBT), tantalum oxide (Ta₂O₅), various lanthanide oxides, and so forth, are also being investigated to allow further device scaling. Such dielectrics, with dielectric constants greater than about 7, are referred to herein as “high k dielectrics” or “high k materials”.

Similar high quality, thin dielectric layers are desirable in other contexts of integrated circuit fabrication. Many designs call for integrated capacitors in memory arrays to exhibit a certain minimum capacitance for proper data storage and retrieval. Some efforts to increase capacitance for a given memory cell space have focused on the use of materials characterized by high dielectric constants, such as those listed above.

### SUMMARY OF THE INVENTION

Although high k materials advantageously allow the gate dielectric thickness to be reduced without introducing quantum effects, when electrode materials such as doped silicon or silicon germanium alloys are deposited over many of the high k materials currently under investigation, interface problems such as reaction and trapping effects often arise, thus resulting in defective devices. For example, when HfO₂ layers are combined with conventional low pressure chemical vapor deposition (LPCVD) polycrystalline silicon (“polysilicon”) deposited at about 620° C., electrically shorted devices are often obtained. Additionally, trapping effects at the HfO₂-polysilicon interface can introduce electrical defects. To avoid these problems, the gate dielectric can be capped with an intermediate layer before electrode deposition.

In accordance with the foregoing, in accordance with one aspect of the present invention, a method for forming an integrated circuit structure on a semiconductor substrate comprises loading the semiconductor substrate into a processing chamber. The method further comprises depositing a gate dielectric over the semiconductor substrate using an atomic layer deposition process. The gate dielectric comprises a high k material. The method further comprises depositing a silicon oxide layer over the gate dielectric material in a rapid thermal chemical vapor deposition process. In one embodiment, SiH₄ and N₂O are used as the silicon and oxygen source gases, respectively. The method further comprises forming a gate electrode over the silicon oxide layer. The method further comprises removing the semiconductor substrate from the processing chamber.

In another aspect of the present invention, a method comprises providing a high k material. The method further comprises depositing silicon oxide on the high k material in a rapid thermal chemical vapor deposition process. The method further comprises forming a gate electrode over the silicon oxide.

In another aspect of the present invention, a thin film transistor apparatus comprises a semiconductor substrate. The apparatus further comprises a gate dielectric material positioned over the semiconductor substrate. The gate dielectric material has a dielectric constant greater than approximately 7. The apparatus further comprises a silicon oxide capping layer positioned on the gate dielectric material. The apparatus further comprises a gate electrode formed on the capping layer.

In another aspect of the present invention, a semiconductor apparatus comprises an oxide capping layer positioned between a high k gate dielectric material and a gate electrode.

### BRIEF DESCRIPTION OF THE DRAWINGS

Exemplary embodiments of the silicon oxide capping structures and techniques are illustrated in the accompanying drawings, which are for illustrative purposes only. The drawings comprise the following figures, in which like numerals indicate like parts.

FIG. 1 is a schematic sectional view of an exemplary single-substrate reaction chamber that can be used to produce certain of the structures disclosed herein.

FIG. 2 is a schematic illustration of a transistor structure that includes a capping layer over a high k dielectric layer.

FIG. 3 is a plot of the capping layer thickness as a function of deposition time using processing parameters of an exemplary embodiment.

FIG. 4 is a plot of the surface voltage on a high k stack as a function of deposited charge.

FIG. 5 illustrates the equivalent oxide thickness (EOT) of the dielectric layers in the four transistor structures having Q-V curves shown in FIG. 4, as calculated based on the slope of the Q-V curves, where each dielectric includes a SiO₂ capping layer of different thickness.

FIG. 6 is a plot of flatband voltage for a HfO₂ layer over a 2 nm SiO₂ layer as a function of thickness of the HfO₂ layer.

FIG. 7 illustrates a plot of flatband voltage for a 5 nm HfO₂ layer with an overlying SiO₂ capping layer as a function of thickness of the capping layer.

FIG. 8 is a flowchart illustrating an exemplary method of depositing a metal oxide using an atomic layer deposition (ALD) process.

FIG. 9 is a flowchart illustrating an exemplary method of forming a transistor structure that includes a capping layer over a high k dielectric layer.

### DETAILED DESCRIPTION OF PREFERRED EMBODIMENTS

Introduction.

As described above, high k materials advantageously allow effective electrical gate dielectric thickness to be reduced without introducing deleterious quantum effects. High k layers can be deposited by atomic layer deposition (ALD), which is a chemically self-limiting process, whereby alternated pulses of reaction precursors saturate a substrate and leave no more than one monolayer of material per pulse. Temperatures are maintained above condensation levels and below thermal decomposition levels for the reactants. The precursors are selected to ensure self-saturating reactions, because an adsorbed layer in one pulse leaves a surface termination that is non-reactive with the gas phase reactants of the same pulse. A subsequent pulse of different reactants does react with the previous termination to enable continued deposition. Thus, each cycle of alternated pulses leaves no more than about one molecular layer of the desired material. The principles of ALD type processes are presented in T. Suntola in the Handbook of Crystal Growth 3, Thin Films and Epitaxy, Part B: Growth Mechanisms and Dynamics, Chapter 14, Atomic Layer Epitaxy, pp. 601-663, Elsevier Science B.V. 1994.

For example, a thin hafnium oxide (HfO₂) film having high stability at high temperatures, and a low leakage current, can be deposited by ALD using a HfCl₄/H₂O chemistry at about 300° C. Between 20 and 100 cycles of HfCl₄/H₂O result in HfO₂ gate stacks having a thickness between approximately 1 nm and approximately 5 nm. Similarly, hafnium silicate films can be deposited by ALD by pulsing sequentially 3-aminopropyltriethoxy silane (APTES), ozone (O₃), hafnium chloride (HfCl₄) and water (H₂O) at 300° C.

However, as explained above, when electrode materials such as doped silicon or silicon germanium alloys are deposited over high k materials, interface problems such as reaction and trapping effects often arise, thus resulting in defective devices. These integration difficulties can advantageously be reduced by capping the high k material with a thin protective layer before deposition of the silicon electrode layer. Exemplary high k materials include, but are not limited to, aluminum oxide (Al₂O₃), zirconium oxide (ZrO₂), hafnium-based oxides (HfO₂, AlHfO, HfSiOₓ, HfSiON), barium strontium titanate (BST), strontium bismuth tantalate (SBT), tantalum oxide (Ta₂O₅), various lanthanide oxides, and so forth. Exemplary lanthanide oxides include lanthanum oxide, neodymium oxide and cerium dioxide. Generally, high k materials include oxides of Group 4 and Group 5 metals.

At the outset, it should be noted that while the exemplary embodiments described herein are couched in the context of transistor gate stacks, the principle of capping a high k material with a thin protective layer can be applied to a variety of contexts in which layers are to be deposited over high k materials. An example of such a context is the formation of capacitor electrodes over high k dielectrics, as proposed for high density memory cells in random access memory (RAM) arrays. Likewise, while the methods described herein are particularly advantageous for depositing silicon-containing layers over high k materials, the principles and advantages described herein can also be used in the deposition of metallic electrodes over high k materials.

Reactor Structure.

Before the capping layer is described in greater detail, the preferred reactor for depositing silicon-containing layers by chemical vapor deposition (CVD) is first described below. While not illustrated separately, the ALD processes described herein can be performed in a Pulsar™ 2000 ALCVD™ Reactor, commercially available from ASM Microchemistry Oy (Espoo, Finland).

The exemplary embodiments disclosed herein are presented in the context of a single-substrate, horizontal flow cold-wall reactor. Generally, single wafer processing tools demonstrate greater process control and uniformity than traditional batch systems, but do so at the expense of throughput, since only a small number of substrates can be processed at one time. The single-pass horizontal flow design also enables laminar flow of reactant gases, with low residence times, which in turn facilitates sequential processing while minimizing reactant interaction with each other and with chamber surfaces. Thus, among other advantages, a laminar flow enables sequentially flowing reactants that might adversely react with each other. Reactions to be avoided include highly exothermic or explosive reactions, such as produced by oxygen and hydrogen-bearing reactants, and reactions that produce particulate contamination of the chamber.

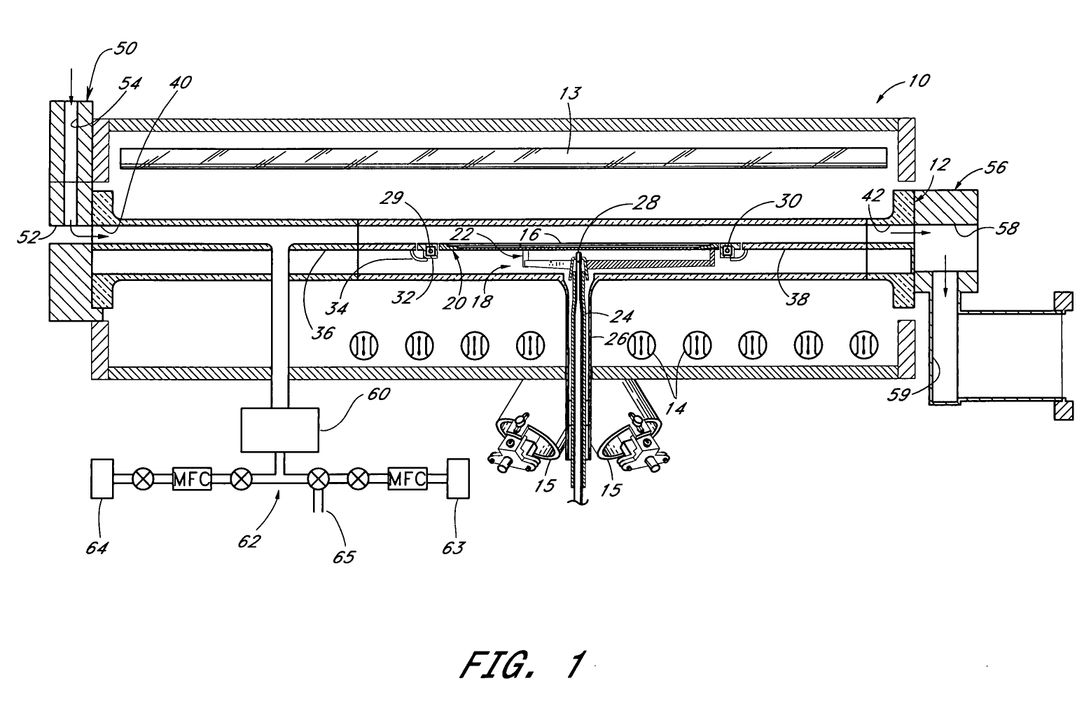

FIG. 1 shows a CVD reactor 10, including a quartz process or reaction chamber 12, constructed in accordance with an exemplary embodiment, and which can be used with the methods disclosed herein. While originally designed to optimize epitaxial deposition of silicon on a single substrate at a time, the superior processing control of the illustrated reactor 10 has utility in CVD of a number of different materials. Moreover, the illustrated reactor 10 can safely and cleanly accomplish multiple treatment steps sequentially in the same chamber 12. The basic configuration of the reactor 10 is available commercially under the trade name Epsilon® from ASM America, Inc. (Phoenix, Ariz.).

A plurality of radiant heat sources are supported outside the chamber 12 to provide heat energy in the chamber 12 without appreciable absorption by the quartz chamber walls. While the exemplary embodiments disclosed herein are described in the context of a “cold wall” CVD reactor for processing semiconductor wafers, it will be understood that the processing methods described herein can be used in conjunction with other heating/cooling systems, such as those employing inductive or resistive heating.

The illustrated radiant heat sources comprise an upper heating assembly of elongated tube-type radiant heating elements 13. The upper heating elements 13 are preferably disposed in spaced-apart parallel relationship and also are substantially parallel with the reactant gas flow path through the underlying reaction chamber 12. A lower heating assembly comprises similar elongated tube-type radiant heating elements 14 below the reaction chamber 12, preferably oriented transverse to the upper heating elements 13. Desirably, a portion of the radiant heat is diffusely reflected into the chamber 12 by rough specular reflector plates (not shown) above and below the upper and lower heating elements 13, 14, respectively. Additionally, a plurality of spot lamps 15 supply concentrated heat to the underside of the substrate support structure (described below), to counteract a heat sink effect created by cold support structures extending through the bottom of the reaction chamber 12.

Each of the elongated tube type heating elements 13, 14 is preferably a high intensity tungsten filament lamp having a transparent quartz envelope containing a halogen gas, such as iodine. Such lamps produce full-spectrum radiant heat energy transmitted through the walls of the reaction chamber 12 without appreciable absorption. As is known in the art of semiconductor processing equipment, the power of the heating elements 13, 14 and spot lamps 15 can be controlled independently or in grouped zones in response to temperature sensors.

A workpiece or substrate, preferably comprising a silicon wafer 16, is shown supported within the reaction chamber 12 upon a substrate support structure 18. Note that, while the substrate of the illustrated embodiment is a single-crystal silicon wafer, it will be understood that the term “substrate” broadly refers to any surface on which a layer is to be deposited. Moreover, the principles and advantages described herein apply equally well to depositing layers over numerous other types of substrates, including, without limitation, glass substrates such as those employed in flat panel displays.

The illustrated support structure 18 includes a substrate holder 20, upon which the wafer 16 rests, and a support spider 22. The spider 22 is mounted to a shaft 24, which extends downwardly through a tube 26 depending from the chamber lower wall. Preferably, the tube 26 communicates with a source of purge or sweep gas which can flow during processing, inhibiting process gases from escaping to the lower section of the chamber 12.

A plurality of temperature sensors are positioned in proximity to the wafer 16. The temperature sensors can take any of a variety of forms, such as optical pyrometers or thermocouples. The number and positions of the temperature sensors are selected to promote temperature uniformity. Preferably, the temperature sensors directly or indirectly sense the temperature of positions in proximity to the wafer.

In the illustrated embodiment, the temperature sensors comprise thermocouples, including a first or central thermocouple 28, suspended below the substrate holder 20 in a suitable fashion. The illustrated central thermocouple 28 passes through the spider 22 in proximity to the substrate holder 20. The reactor 10 further includes a plurality of secondary or peripheral thermocouples, also in proximity to the wafer 16, including a leading edge or front thermocouple 29, a trailing edge or rear thermocouple 30, and a side thermocouple (not shown). Each of the peripheral thermocouples is housed within a slip ring 32, which surrounds the substrate holder 20 and the wafer 16. Each of the central and peripheral thermocouples are connected to a temperature controller, which sets the power of the heating elements 13, 14 and spot lamps 15 in response to programmed setpoints, control algorithms, and the readings of the thermocouples.

In addition to housing the peripheral thermocouples, the slip ring 32 absorbs and emits radiant heat during high temperature processing, such that it compensates for a tendency toward greater heat loss or absorption at wafer edges, a phenomenon which is known to occur due to a greater ratio of surface area to volume in regions near such edges. By minimizing edge losses, the slip ring 32 can reduce the risk of radial temperature non-uniformities across the wafer 16. The slip ring 32 can be suspended by any suitable means. For example, the illustrated slip ring 32 rests upon elbows 34 that depend from a front chamber divider 36 and a rear chamber divider 38. The dividers 36, 38 desirably are formed of quartz. In some arrangements, the rear divider 38 can be omitted.

The illustrated reaction chamber 12 includes an inlet port 40 for the injection of reactant and carrier gases, and the wafer 16 can also be received through the inlet port 40. An outlet port 42 is on the opposite side of the chamber 12, with the wafer support structure 18 positioned between the inlet port 40 and the outlet port 42.

An inlet component 50 is fitted to the reaction chamber 12, is adapted to surround the inlet port 40, and includes a horizontally elongated slot 52 through which the wafer 16 can be inserted. A generally vertical inlet 54 receives gases from remote sources, as will be described more fully below, and communicates such gases with the slot 52 and the inlet port 40. The inlet 54 can include gas injectors as described in U.S. Pat. No. 5,221,556 (issued to Hawkins, et al.), or as described with respect to FIGS. 21-26 of U.S. Pat. No. 6,093,252 (issued to Wengert, et al.), the disclosures of which are hereby incorporated by reference. Such injectors are designed to maximize uniformity of gas flow for the single-wafer reactor.

An outlet component 56 similarly mounts to the process chamber 12 such that an exhaust opening 58 aligns with the outlet port 42 and leads to exhaust conduits 59. The exhaust conduits 59, in turn, can communicate with suitable vacuum means (not shown) for drawing process gases through the chamber 12. In an exemplary embodiment, process gases are drawn through the reaction chamber 12 and a downstream scrubber (not shown). A pump or fan is preferably included to aid in drawing process gases through the chamber 12, and to evacuate the chamber for low pressure processing.

The reactor 10 also optionally includes an excited species source 60, preferably positioned upstream from the chamber 12. The excited species source 60 of the illustrated embodiment comprises a remote plasma generator, including a magnetron power generator and an applicator along a gas line 62. An exemplary remote plasma generator is available commercially under the trade name TRW-850 from Rapid Reactive Radicals Technology (R3T) GmbH (Munich, Germany). In the illustrated embodiment, microwave energy from a magnetron is coupled to a flowing gas in an applicator along a gas line 62. A precursor gas source 63 is coupled to the gas line 62 for introduction into the excited species source 60. A carrier gas source 64 is also coupled to the gas line 62. One or more further branch lines 65 can also be provided for additional reactants. As is known in the art, the gas sources 63, 64 can comprise gas tanks, bubblers, and so forth, depending upon the form and volatility of the reactant species. Each gas line can be provided with a separate mass flow controller (MFC) and valves, as shown, to allow selection of relative amounts of carrier and reactant species introduced to the excited species source 60 and thence into the reaction chamber 12. It will be understood that, in other arrangements, the excited species can be generated within the process chamber. The preferred processes described below, however, do not employ excited species but are rather species of thermal CVD.

In an exemplary embodiment, wafers are passed from a handling chamber (not shown), which is isolated from the surrounding environment, through the slot 52 by a pick-up device. In an exemplary embodiment, the handling chamber and the processing chamber 12 are separated by a gate valve (not shown) of the type disclosed in U.S. Pat. No. 4,828,224 (issued to Crabb, et al.), the disclosure of which is hereby incorporated herein by reference.

The total volume capacity of a single-wafer process chamber 12 designed for processing 200 mm wafers, for example, is preferably less than about 30 liters, more preferably less than about 20 liters, and most preferably less than about 10 liters. The illustrated chamber 12 has a capacity of about 7.5 liters. Because the illustrated chamber 12 is divided by the dividers 36, 38, substrate holder 20, slip ring 32, and the purge gas flowing from the tube 26, however, the effective volume through which process gases flow in the upper portion of the chamber 12 is around half the total volume (about 3.77 liters in the illustrated embodiment). Of course, it will be understood that the volume of the single-wafer process chamber 12 can be different, depending upon the size of the wafers for which the chamber 12 is designed to accommodate. For example, a single-wafer processing chamber 12 of the illustrated type, but for 300 mm wafers, preferably has a capacity of less than about 100 liters, more preferably less than about 60 liters, and most preferably less than about 30 liters. One 300 mm wafer processing chamber has a total volume of about 24 liters, with an effective processing gas capacity of about 11.83 liters.

As mentioned, a plurality of vapor-phase precursor sources (not shown) are connected to the inlet 54 via gas lines with attendant safety and control valves, as well as MFCs, which are coordinated at a gas panel. Process gases are communicated to the inlet 54 in accordance with directions programmed into a central controller and distributed into the process chamber 12 through injectors. After passing through the process chamber 12, process gases that have not reacted and gaseous reaction by-products are exhausted to a scrubber to condense environmentally dangerous fumes before exhausting to the atmosphere.

The gas sources preferably include a source of carrier gas. Preferably, the carrier gas comprises an inert gas such as nitrogen (N₂). Nitrogen gas is relatively inert and compatible with many integrated materials and process flows. Other possible inert carrier gases include noble gases, such as helium (He) or argon (Ar). A source of hydrogen gas (H₂) can also be provided to the reactor 10, as certain silicon deposition processes use H₂.

The vapor-phase sources can include liquid reactant sources. The liquid source can comprise, for example, liquid dichlorosilane (DCS), trichlorosilane (TCS), or metallorganic sources in a bubbler, and a gas line for bubbling and carrying vapor phase reactants from the bubbler to the reaction chamber 12. The bubbler can alternatively (or additionally) hold liquid tantalum ethoxide (Ta(OC₂H₅)₅) as a metal source, while a gas line serves to bubble carrier gas through the liquid metal source and transport metallorganic precursors to the reaction chamber 12 in gaseous form.

In an exemplary embodiment, the reactor 10 also includes other source gases such as dopant sources (for example, phosphine (PH₃), arsine (AsH₃) and diborane (B₂H₆)) and etchants for cleaning the reactor walls and other internal components (for example, hydrochloric acid (HCl) or NF₃/Cl₂ provided as the plasma source gas for feeding the excited species source 60). For deposition of polycrystalline silicon germanium (poly-SiGe) in accordance with some embodiments, a source of germanium (for example, germane (GeH₄)) can also be provided for doping or formation of silicon germanium (SiGe) films.

In an exemplary embodiment, a silicon source is also provided. As is known in the art, silanes, including monosilane (SiH₄), DCS and TCS, are common volatile silicon sources for CVD applications, such as the deposition of poly-SiGe, silicon nitride, metal silicides, and extrinsic or intrinsic silicon (polycrystalline, amorphous or epitaxial, depending upon deposition parameters). Other possible silicon sources include disilane (Si₂H₆), trisilane (Si₃H₈) and tetrasilane (Si₄H₁₀). Non-halogenated silanes such as monosilane, disilane, trisilane and tetrasilane are preferred to avoid chlorine incorporation into sensitive gate dielectric structures.

Deposition of High k Materials.

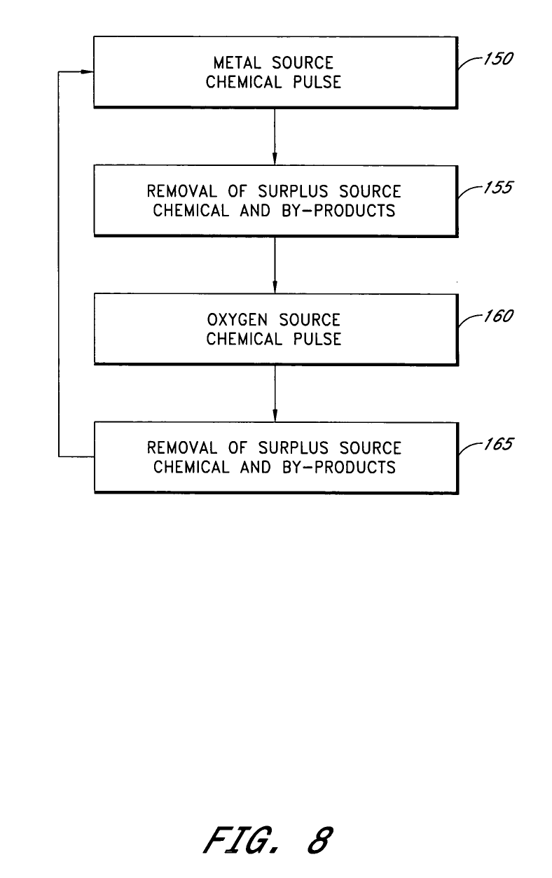

As described above, layers of high k materials can be deposited in an ALD process, whereby deposition of vaporized high k material onto a surface is based on sequential and alternating self-saturating surface reactions. For example, alternating vapor-phase pulses of a metal source chemical and an oxygen source chemical are fed to a reaction chamber having a reduced pressure and contacted with a heated substrate surface to form a metal oxide then film. The source chemical pulses are separated from each other by removal steps, such as by flowing inert or noble gas, so that gas phase reactions are avoided and only self-saturating surface reactions are enabled. The ALD processes described herein can be performed in a Pulsar™ 2000 ALCVD™ Reactor, commercially available from ASM Microchemistry Oy (Espoo, Finland). The general process is illustrated in FIG. 8. Additional information about ALD processes is disclosed in U.S. Patent Application Publication 2002/0115252 A1, published 22 Aug. 2002, the entire disclosure of which is hereby incorporated herein by reference.

Generally, the metal source chemical is selected from a group of compounds that are volatile and thermally stable at the substrate temperature. The oxygen source chemicals are selected from volatile or gaseous compounds that contain oxygen and that are capable of reacting with the metal source compound on the substrate surface. Exemplary oxygen source materials include, but are not limited to, hydrogen peroxide, O₃, oxygen with unpaired electrons, H₂O, and alcohols (such as methanol, ethanol and isopropanol.

In an exemplary, ALD process, a substrate is loaded into a reaction space. The reaction space is adjusted to the desired temperature and the gas atmosphere of the reaction space is adjusted to the desired pressure. A repeatable process sequence including four basic operations, as depicted in FIG. 8, is begun.

In the exemplary method illustrated in FIG. 8, a vapor phase pulse 150 of a metal source chemical is introduced into the reaction space and contacted with the substrate surface. After a first contact time sufficient to saturate the surface and leave no more than one monolayer of adsorbed reactant, the surplus metal source chemical and possible reaction byproducts are removed 155 from the reaction space by varying the reaction space pressure and/or by inert gas flow. After a first purging time a vapor phase pulse 160 of an oxygen source is introduced into the reaction chamber and contacted with the substrate surface. After a second contact time the surplus oxygen source chemical and possible reaction byproducts are removed 165 from the reaction space by varying the reaction space pressure and/or by inert gas flow. After a second purging time the illustrated process cycle is repeated until a metal oxide thin film of a desired thickness is obtained. After the desired thickness is obtained, the substrate having the thin film can be transferred to a different reaction chamber for deposition of a capping layer, described in greater detail below.

For example, to grow a thin film of HfO₂ using the ALD process described herein, HfCl₄ vapor is introduced into an ALD reaction chamber and is exposed to the substrate surface for approximately 1.5 seconds. This is referred to as Pulse A. The reaction chamber is then purged with nitrogen gas for approximately 3.0 seconds to remove surplus HfCl₄ and byproducts from the reaction chamber. This is referred to as Purge A. Then water vapor is introduced to the reaction chamber and exposed to the wafer surface for approximately 3.0 seconds. This is referred to as Pulse B. Residual H₂O and reaction byproducts are then removed by purging the reaction chamber for approximately 4.0 seconds. This is referred to as Purge B. During the reaction phases, the reactants are supplied in sufficient quantity to saturate the substrate surface. This exemplary high k deposition cycle is summarized in TABLE A.

TABLE A

| Phase | Reactant | Temperature | Pressure | Time |
|---|---|---|---|---|
| Pulse A | HfCl₄ | 300° C. | 5 mbar-10 mbar | 1.5 sec |
| Purge A | — | 300° C. | 5 mbar-10 mbar | 3.0 sec |
| Pulse B | H₂O | 300° C. | 5 mbar-10 mbar | 3.0 sec |
| Purge B | — | 300° C. | 5 mbar-10 mbar | 4.0 sec |

In one embodiment, the cycle of TABLE A, consisting of Pulse A, Purge A, Pulse B, Purge B, is repeated 60 times. The average deposition rate is about 0.50 Å cycle⁻¹ at 300° C., such that the resulting HfO₂ thickness is about 30 Å.

The processing parameters provided in TABLE A are exemplary, and other parameters can be used in other embodiments. For example, temperatures during the process can generally be between approximately 200° C. and approximately 500° C. For an amorphous HfO₂ layer, the temperature is generally at the low end of this range, between approximately 200° C. and approximately 250° C., and at approximately 225° C. in one particular embodiment. For a crystalline film, the temperature is generally at the high end of this range, between approximately 250° C. and approximately 500° C., and at approximately 300° C. in one particular embodiment. Mixtures of amorphous and crystalline composition result at the boundary of these two regimes. The processing parameters provided in TABLE A produce a largely crystalline HfO₂ film.

Capping Layers: Formation and Characteristics.

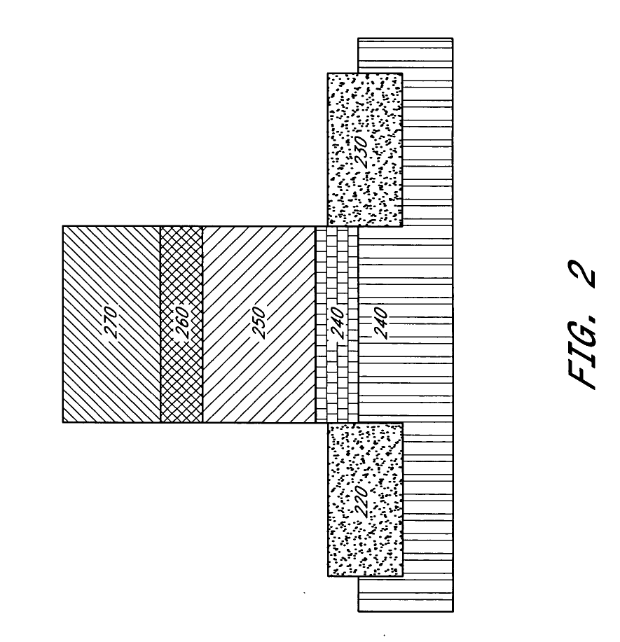

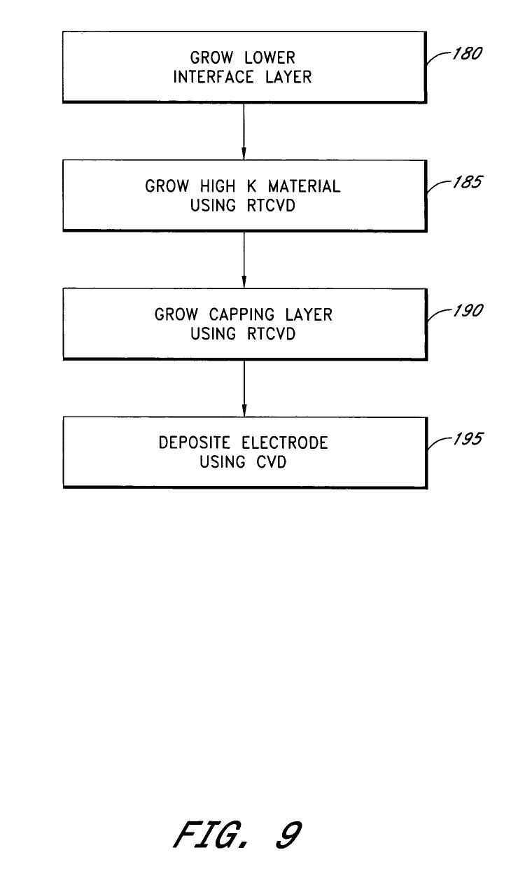

In an exemplary embodiment, a silicon oxide capping layer is formed over the gate dielectric by rapid thermal chemical vapor deposition (RTCVD) in a single wafer reactor using SiH₄ and nitrous oxide (N₂O). An exemplary embodiment of the resulting transistor structure is illustrated in FIG. 2. Specifically, FIG. 2 illustrates a thin film transistor (TFT) structure formed on a silicon substrate 210, and having a source 220, a drain 230, a high k gate dielectric layer 250, and a gate electrode 270. Although the transistor structure illustrated in FIG. 2 has elevated an source 220 and drain 230, elevation of these structures is optional. As illustrated, the gate dielectric layer 250 is bordered by a lower interface layer 240, which comprises a silicon oxide or SiON film that is between approximately 0.3 nm and approximately 1.5 nm thick in an exemplary embodiment. An exemplary method for forming the structure illustrated in FIG. 2 is provided in FIG. 9.

Referring now to FIGS. 2 and 9, in an exemplary embodiment, the lower interface layer 240 is formed in an operational block 180 by a technique such as wet chemical treatment, thermal oxidation, or radical assisted oxidation. A high k gate dielectric layer 250 is then formed over the lower interface layer 240 in an operational block 185. In one embodiment, the gate dielectric layer 250 comprises a material having a dielectric constant greater than approximately 7, in another embodiment the gate dielectric layer 250 comprises a material having a dielectric constant greater than approximately 10, and in still another embodiment, the gate dielectric layer 250 comprises a material having a dielectric constant greater than approximately 12. In an exemplary embodiment, the gate dielectric comprises a metal oxide. In a modified embodiment, the lower interface layer 240 is omitted, and the high k gate dielectric layer 250 is formed directly on the silicon substrate 210.

As described above, to avoid causing adverse reaction and trapping effects at the interface between the high k and polysilicon layers, a thin silicon oxide capping layer 260 is positioned between the gate dielectric layer 250 and the gate electrode 270. This capping layer 260 is formed in operational block 190 illustrated in FIG. 9. Generally, the silicon oxide capping layer 260 is not formed using the same methods as the silicon oxide lower interface layer 240. Rather, the capping layer 260 is formed by RTCVD using SiH₄ and N₂O. In particular, exemplary processing parameters for forming the silicon oxide capping layer 260 are provided in TABLE B. Additionally, TABLE B provides two sets of ranges of processing parameters in which modified embodiments can operate; these modified embodiments can be used to produce capping layers 260 having other properties.

TABLE B

| Parameter | Exemplary | Preferred | More Preferred |
|---|---|---|---|
| (unit) | Value | Range | Range |
| temperature (° C.) | 700 | 600-800 | 650-750 |
| N₂ flow rate (slm) | 20 | 10-30 | 15-25 |
| SiH₄ flow rate (sccm) | 45 | 30-60 | 40-50 |
| N₂O flow rate (slm) | 2.5 | 1.5-3.5 | 2.0-3.0 |
| reactor pressure (torr) | 25 | 15-35 | 20-30 |
| deposition time (sec) | 10-120 | 5-180 | 5-150 |
| deposition rate (Å min⁻¹) | 10-15 | 5.0-25 | 7.5-20 |

The exemplary parameters listed in TABLE B are particularly well-suited for clustering on one tool with a reactor to deposit the underlying high k gate dielectric layer. Other processing parameters can be used in other embodiments to create capping layers over the high k gate dielectric. For example, in another exemplary embodiment, the deposition temperature can be reduced. A reduced temperature can advantageously reduce the likelihood of an unwanted interaction between the high k material and the N₂O and/or the SiH₄. A reduced temperature can also advantageously reduce or eliminate oxidation of the lower interface layer; oxidation of the lower interface layer would disadvantageously result in an increased layer thickness. A decrease in deposition rate due to decreased temperature can optionally be offset by increasing the partial pressures of SiH₄ and/or N₂O. Exemplary processing parameters for forming the silicon oxide capping layer 260 in such embodiments are provided in TABLE C. Additionally, TABLE C provides two sets of ranges of processing parameters in which modified embodiments can operate; these modified embodiments can be used to produce capping layers 260 having other properties.

TABLE C

| Parameter | Exemplary | Preferred | More Preferred |
|---|---|---|---|
| (unit) | Value | Range | Range |
| temperature (° C.) | 600 | 500-700 | 550-650 |
| N₂ flow rate (slm) | 5 | 1-10 | 2.5-7.5 |
| SiH₄ flow rate (sccm) | 45 | 30-60 | 40-50 |
| N₂O flow rate (slm) | 2.5 | 1.5-3.5 | 2.0-3.0 |
| reactor pressure (torr) | 25 | 15-35 | 20-30 |
| deposition time (sec) | 10-120 | 5-180 | 5-150 |
| deposition rate (Å min⁻¹) | about 5 | 1.0-9.0 | 2.5-7.5 |

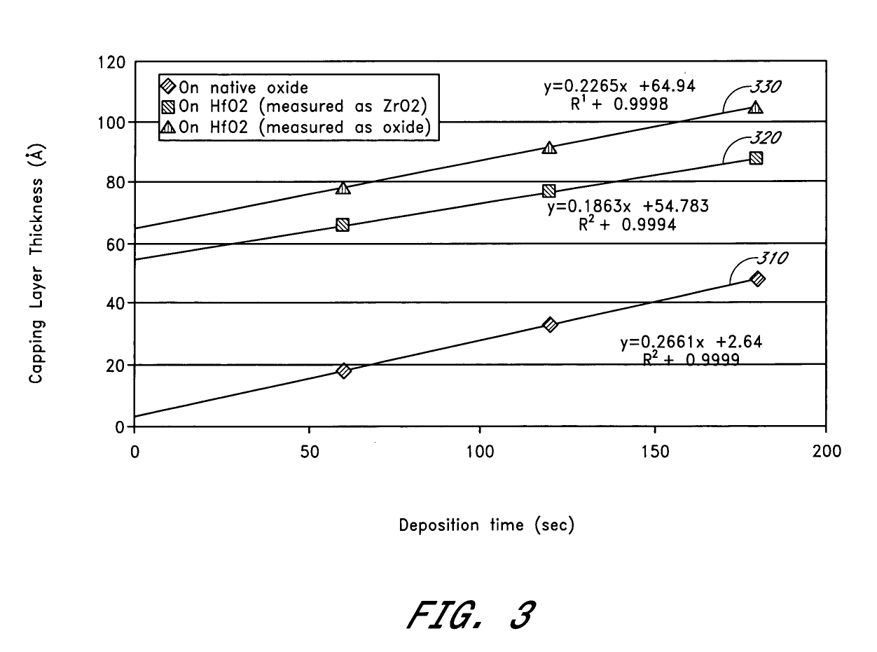

The thickness of the SiO₂ capping layer formed using the parameters set forth in TABLES B and C can be controlled by adjusting various parameters, including the deposition time. Specifically, FIG. 3, which is a plot of the capping layer thickness as a function of deposition time in an embodiment using the values provided in TABLE B, illustrates that, in this exemplary embodiment, the capping layer grows at between approximately 0.5 nm min⁻¹ and approximately 2.5 nm min⁻¹. As evident from FIG. 3, such a layer can be formed over a native oxide layer (line 310), or can be formed over a 5 nm layer of HfO₂ (lines 320 and 330). The capping layer can be formed over other types of oxide layers in other embodiments. Ellipsometry can be used to determine the total oxide thickness after deposition of the SiO₂ capping layer.

The finished capping layer is preferably between approximately 0.3 nm and approximately 2.0 nm thick, is more preferably between approximately 0.3 nm and approximately 1.2 nm thick, and is most preferably between approximately 0.3 nm and approximately 1.0 nm thick. By adjusting the deposition time between approximately 10 seconds and approximately 180 seconds, the thickness of the capping layer can be closely controlled. Preferably, the deposition time is adjusted between approximately 10 seconds and approximately 135 seconds, and more preferably, the deposition time is adjusted between approximately 10 seconds and approximately 90 seconds. In one embodiment, the deposition time is less than 180 seconds, and in another embodiment, the deposition time is less than 60 seconds. Furthermore, these parameters advantageously provide a process that is sufficiently fast to achieve commercially acceptable throughput using a single wafer reactor.

In the exemplary embodiment illustrated in FIG. 2, after formation of the capping layer 260, a gate electrode 270 is deposited thereon in an operational block 195. In one embodiment, the gate electrode 270 comprises polysilicon, although other materials can be used in other embodiments, such as poly-SiGe. In still other embodiments, the gate electrode 270 comprises a work function-tailored metallic material. The gate electrode 270 can be formed using a CVD process in the same deposition chamber as that used to deposit the capping layer 260. However, in other embodiments, the gate electrode 270 is formed in a different deposition chamber from that used to deposit the capping layer 260.

As described herein, deposition of a capping layer over a high k material provides several advantageous electrical properties. For example, certain capping layers can provide electrically more passive interfaces with the high k material, as compared to a direct interface between the high k material and the polysilicon gate electrode. In particular, silicon oxides are generally stable when in contact with both HfO₂ and polysilicon at high temperatures (for example, over 1000° C.). Other electrical advantages of the capping layer can be demonstrated by depositing an electrical charge on the surface of the capping layer, such as by using a non-contact electrical metrology tool capable of depositing a corona charge, and measuring the surface voltage as a function of deposited charge.

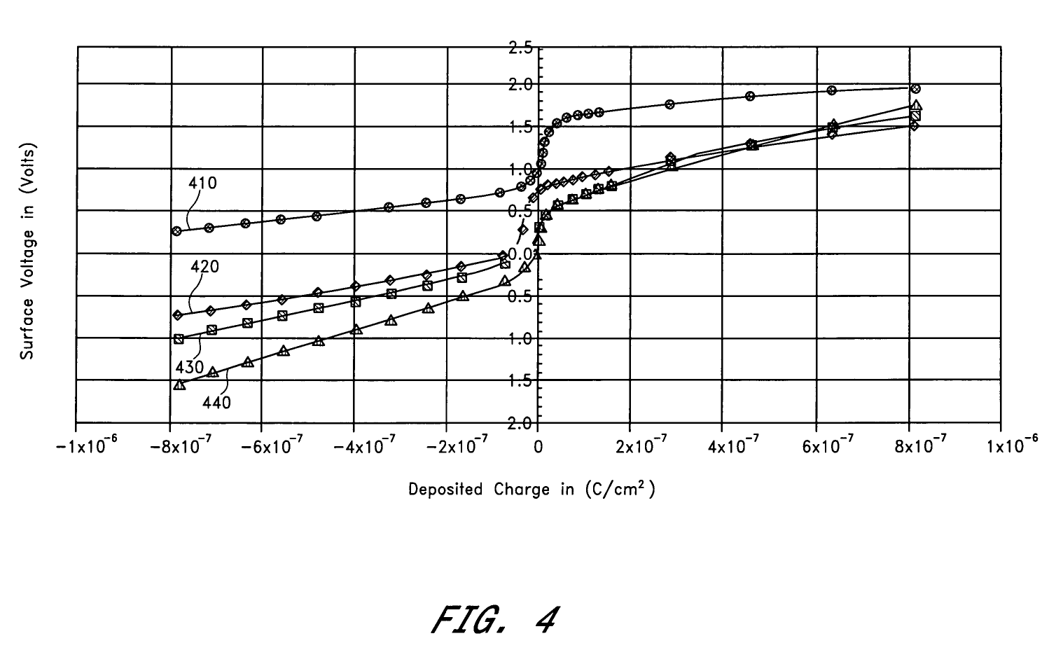

For example, silicon oxide capping layers have a lower density of fixed charges than other materials, such as Al₂O₃ and Si₃N₄. FIG. 4 is a plot of the surface voltage on a TFT structure as a function of deposited charge (“Q-V curve”). Specifically, line 410 is a Q-V curve for a 5 nm thick layer of HfO₂ with no overlying capping layer, while lines 420, 430 and 440 are Q-V curves for a three different 5 nm thick HfO₂ layers, each with a SiO₂ capping layer having a different thickness. Specifically, line 420 represents a relatively thin SiO₂ capping layer (deposited for approximately 60 seconds), line 430 represents a SiO₂ capping layer having an intermediate thickness (deposited for approximately 120 seconds), and line 440 represents a relatively thick SiO₂ capping layer (deposited for approximately 180 seconds). As illustrated, the Q-V curves are well-developed: they closely resemble Q-V curves for ideal capacitors without charge trapping or charge leakage. This indicates that the SiO₂ capping layers have advantageous electrical properties.

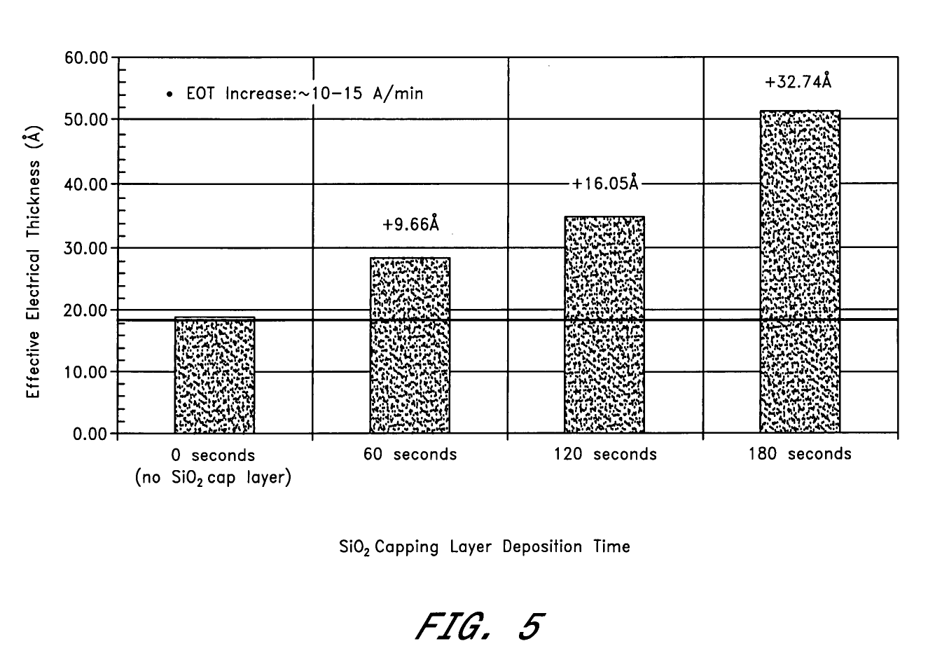

The effective electrical thickness of the TFT structure can be derived from the slope of the Q-V curves that are illustrated in FIG. 4. Specifically, FIG. 5 illustrates the equivalent oxide thickness (EOT) of the four transistor dielectric structures having Q-V curves shown in FIG. 4, as calculated based on the slope of the Q-V curves. FIG. 5 confirms that, in this embodiment, the equivalent oxide thickness (“EOT”) increases at between approximately 10 Å min⁻¹ and approximately 15 Å min⁻¹.

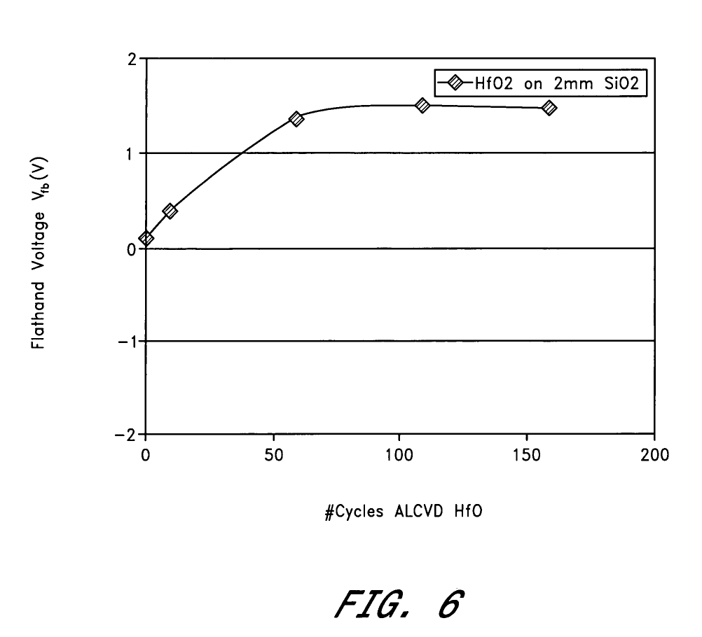

The advantageous properties of deposition of a capping layer over a high k material are also evident upon evaluation of the flatband voltage of TFT structures with and without the capping layer. Flatband voltage measurements can be obtained from non-contact electrical measurements. For example, FIG. 6 is a plot of flatband voltage for a HfO₂ layer as a function of thickness of the layer, as measured by the number of deposition cycles used to form the layer. The HfO₂ layer of FIG. 6 was deposited over a silicon oxide lower interface layer 240 (see FIG. 2) having a thickness of approximately 2 nm. No capping layer was deposited over the HfO₂ layer of FIG. 6. As illustrated, deposition of HfO₂ over the lower interface layer 240 results in an increase of the flatband voltage as comported to the flatband voltage (approximately 0 volts) of the lower interface layer 240 without the overlying HfO₂ layer.

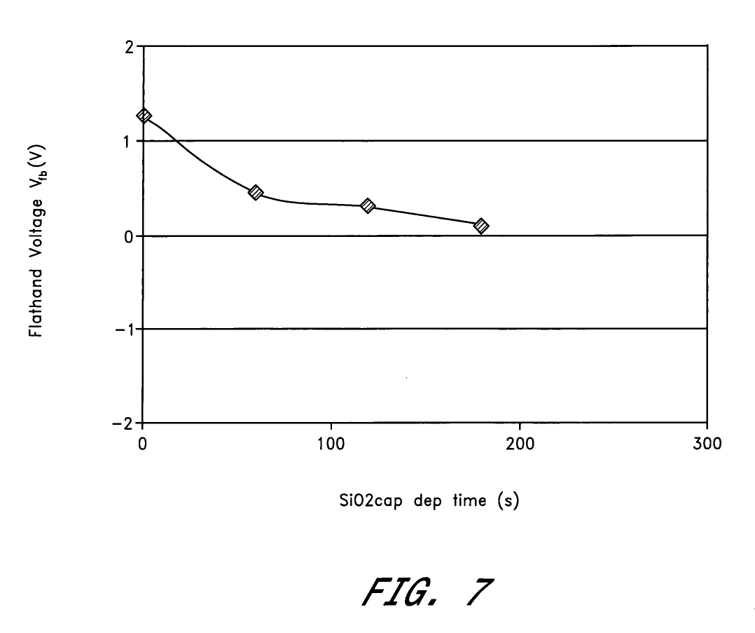

FIG. 7 illustrates a plot of flatband voltage for a 5 nm HfO₂ layer with an overlying SiO₂ capping layer as a function of thickness of the capping layer. As illustrated, deposition of the capping layer results in a significant reduction of the flatband voltage of the structure. In particular, thicker capping layers cause the flatband voltage to approach the flatband voltage of the SiO₂ lower interface layer 240—approximately 0 volts—as illustrated in FIG. 6. This illustrates that the capping layer, when deposited using the methods disclosed herein, can beneficially influence electrical properties of high k gate dielectrics.

In addition to providing advantageous electrical properties, deposition of a cap layer over a high k gate dielectric can reduce the likelihood of reactions between the high k material and an overlying polysilicon electrode during deposition of the polysilicon, or during later processing steps at high temperatures. In particular, a silicon oxide cap generally forms a more stable interface with polysilicon than Al₂O₃, Si₃N₄, or other materials. Cap layers also advantageously seal weak spots and defective sites in the high k dielectric layer, and reduce the likelihood of dopant migration between the high k dielectric material and the overlying polysilicon electrode.

The fabrication and use of a SiO₂ capping layer as described herein to provides surprising advantages for fabrication of a transistor structure using high k dielectrics. In particular, it has traditionally be considered more difficult to deposit materials on SiO₂ layers, such that the prior art seeks methods of avoiding gate electrode deposition directly on SiO₂, thus leading to the development of wetting layers to facilitate subsequent deposition steps. Additionally, use of a RTCVD process to create the SiO₂ capping layer has been found to produce surprisingly efficient layers, despite the fact that traditionally CVD processes have been considered to be less controllable than ALD processes.

The methods disclosed herein for forming silicon oxide capping layers can also be used to form more advanced nanolaminates of high k materials and silicon oxide films. For example, these methods can be used to form SiO₂—HfO₂—SiO₂ laminates, HfO₂—SiO₂—HfO₂—SiO₂ laminates, HfO₂—SiO₂—HfO₂ laminates, and SiO₂—HfO₂—SiO₂—HfO₂ laminates, all of which can be used as a gate dielectric. Furthermore, the methods disclosed herein can also be used to combine ultrathin silicon oxide layers with ultrathin silicon nitride layers formed by a remote plasma-enhanced chemical vapor deposition (RPECVD) process, such as CVD employing SiH₄/N*.

### SCOPE OF THE INVENTION

While the foregoing detailed description discloses several embodiments of the present invention, it should be understood that this disclosure is illustrative only and is not limiting of the present invention. It should be appreciated that the specific configurations and operations disclosed can differ from those described above, and that the methods described herein can be used in contexts other than TFT fabrication.

We claim:

1. A method for forming an integrated circuit structure on a semiconductor substrate comprising:
depositing a gate dielectric over the semiconductor substrate using an atomic layer deposition process, wherein the gate dielectric comprises a high k material;
depositing a silicon oxide layer over the gate dielectric material in a rapid thermal chemical vapor deposition process, using SiH₄ and N₂O as silicon and oxygen source gases, respectively; and
forming a gate electrode over the silicon oxide layer.

2. The method of claim 1, wherein SiH₄ is used as a silicon source gas for the deposition of the silicon oxide layer.

3. The method of claim 1, wherein N₂O is used as a oxygen source gas for the deposition of the silicon oxide layer.

4. The method of claim 1, wherein the silicon oxide layer comprises SiO₂.

5. The method of claim 1, wherein the silicon oxide layer comprises SiON.

6. The method of claim 1, wherein the silicon oxide layer is deposited at a rate that is between approximately 5 Å min⁻¹ and approximately 25 Å min⁻¹.

7. The method of claim 1, wherein the silicon oxide layer is deposited at a temperature between approximately 500° C. and approximately 800° C.

8. The method of claim 1, wherein the silicon oxide layer is deposited at a temperature between approximately 600° C. and approximately 700° C.

9. The method of claim 1, further comprising growing a lower interface layer on the semiconductor substrate, the lower interface layer configured to form an interface between the semiconductor substrate and the gate dielectric.

10. The method of claim 9, wherein the lower interface layer comprises silicon oxide.

11. The method of claim 1, wherein the silicon oxide layer has a thickness between approximately 0.3 nm and approximately 2.0 nm.

12. The method of claim 1, wherein the gate dielectric comprises HfO₂.

13. The method of claim 1, wherein the gate dielectric comprises a metal oxide.

14. The method of claim 1, wherein the gate dielectric comprises a material having a dielectric constant of greater than approximately 7.

15. The method of claim 1, wherein the gate electrode comprises polycrystalline silicon.

16. A method of fabricating integrated circuits comprising:
providing a high k material;
depositing silicon oxide on the high k material in a rapid thermal chemical vapor deposition process; and
forming an electrode over the silicon oxide.

17. The method of claim 16, wherein the high k material is formed using an ALD process.

18. The method of claim 16, wherein the electrode is a gate electrode of a transistor structure.

19. The method of claim 16, wherein the electrode is an electrode of a capacitor structure.

20. The method of claim 16, wherein the silicon oxide is deposited at a rate that is between approximately 5 Å min⁻¹ and approximately 25 Å min⁻¹.

21. The method of claim 16, wherein the silicon oxide layer is deposited at a temperature between approximately 500° C. and approximately 800° C.

22. The method of claim 16, further comprising forming an interface layer on a semiconductor substrate prior to providing the high k material.

23. The method of claim 16, further comprising growing an interface layer on a semiconductor substrate prior to providing the high k material, and wherein the interface layer comprises silicon oxide.

24. The method of claim 16, wherein SiH₄ and N₂O are used as silicon and oxygen sources, respectively, in depositing the silicon oxide.

25. The method of claim 16, wherein the silicon oxide is deposited to a thickness of between approximately 0.3 nm and approximately 2.0 nm.

26. The method of claim 16, wherein the silicon oxide is deposited for less than approximately 180 seconds.

27. The method of claim 16, wherein the silicon oxide is deposited for less than approximately 60 seconds.

28. The method of claim 16, wherein the silicon oxide is deposited for between approximately 10 seconds and approximately 135 seconds.

29. The method of claim 16, wherein the high k material comprises a metal oxide.

30. The method of claim 16, wherein the high k material comprises a material having a dielectric constant of greater than approximately 7.

31. The method of claim 16, wherein the high k material comprises a material having a dielectric constant of greater than approximately 10.

32. The method of claim 16, wherein the electrode comprises polycrystalline silicon.

33. A thin film transistor apparatus comprising:
a semiconductor substrate;
a gate dielectric material positioned over the semiconductor substrate, the gate dielectric material having a dielectric constant greater than approximately 7;
a silicon oxide capping layer positioned on the gate dielectric material; and
a gate electrode formed on the capping layer.

34. The apparatus of claim 33, wherein the capping layer has a thickness between approximately 0.3 nm and approximately 2.0 nm.

35. The apparatus of claim 33, wherein the capping layer has a thickness between approximately 0.3 nm and approximately 1.2 nm.

36. The apparatus of claim 33, wherein the gate dielectric material is in direct contact with the semiconductor substrate.

37. The apparatus of claim 33, wherein the gate electrode comprises polycrystalline silicon germanium.

38. The apparatus of claim 33, further comprising a lower interface layer positioned between the semiconductor substrate and the gate dielectric material.

39. The apparatus of claim 38, wherein the lower interface layer is selected from the group consisting of silicon oxide and silicon oxynitride.

40. The apparatus of claim 38, wherein the lower interface layer has a thickness between approximately 0.3 nm and approximately 1.2 nm.

41. The apparatus of claim 33, wherein the gate dielectric material comprises a metal oxide.

42. The apparatus of claim 33, wherein the gate dielectric material comprises a material having a dielectric constant greater than approximately 10.

43. The apparatus of claim 33, wherein the gate dielectric material is selected from the group consisting of zirconium oxide, hafnium oxide, tantalum oxide, aluminum oxide, barium strontium titanate, strontium bismuth tantalate, and lanthanide oxides.

44. An integrated circuit comprising:
a layer of high k material having a first side and a second side opposite the first side;
an oxide capping layer contacting the first side of the high k layer; and
a conductor contacting the second side of the high k material.

45. The integrated circuit of claim 44, wherein the conductor is a capacitor electrode.

46. The integrated circuit of claim 44, wherein the conductor is a transistor gate electrode;

47. The integrated circuit of claim 46, wherein the high k layer is positioned over a semiconductor substrate.

48. The integrated circuit of claim 47, further comprising a lower interface layer positioned between the semiconductor substrate and the high k layer.

49. The integrated circuit of claim 48, wherein the lower interface layer is selected form the group consisting of silicon oxide and silicon oxynitride.

50. The integrated circuit of claim 48, wherein the lower interface layer has a thickness between approximately 0.3 nm and approximately 1.5 nm.

51. The integrated circuit of claim 46, wherein the transistor gate electrode comprises polycrystalline silicon.

52. The integrated circuit of claim 44, wherein the capping layer has a thickness between approximately 0.3 nm and approximately 2.0 nm.

53. The integrated circuit of claim 44, wherein the capping layer has a thickness between approximately 0.3 nm and approximately 1.2 nm.

54. The integrated circuit of claim 44, wherein the capping layer has a thickness between approximately 0.3 nm and approximately 1.0 nm.

55. The integrated circuit of claim 44, wherein the high k layer comprises a metal oxide.

56. The integrated circuit of claim 44, wherein the high k layer comprises a material having a dielectric constant greater than approximately 10.

57. The integrated circuit of claim 44, wherein the high k layer is selected from the group consisting of zirconium oxide, hafnium oxide, tantalum oxide, aluminum oxide, barium strontium titanate, strontium bismuth tantalate, and lanthanide oxides.
